(19) United States
(12) Patent Application Publication
(10) Pub. No.: US 2025/0351734 A1
(43) Pub. Date: Nov. 13, 2025

(54) SPIN DEVICE USING ASYMMETRIC STRUCTURE OF JUNCTION INTERFACE BETWEEN MAGNETIZATION SEED LAYER AND MAGNETIZATION FREE LAYER

(71) Applicant: IUCF-HYU (INDUSTRY-UNIVERSITY COOPERATION FOUNDATION HANYANG UNIVERSITY), Seoul (KR)

(72) Inventor: Jin Pyo HONG, Seoul (KR)

(21) Appl. No.: 18/580,170

(22) PCT Filed: Jul. 4, 2022
(86) PCT No.: PCT/KR2022/009570

§ 371 Date: Jan. 10, 2025

(30) Foreign Application Priority Data
Jul. 21, 2021 (KR) 10-2021-0095606

(51) Int. Cl. H10N 50/20; G01R 33/07; H10N 50/80; H10N 52/00

(52) U.S. Cl. CPC H10N 50/20; G01R 33/075; H10N 50/80; H10N 52/101

(57) ABSTRACT

A spin device is disclosed in which a magnetic domain wall is moved to the center region of a magnetic free layer. The magnetic domain wall is moved and the perpendicular magnetic anisotropy is changed by avoiding a number of defects distributed at the edge or edge region of the magnetic free layer. So, stable operation of the spin device is secured.

### TECHNICAL FIELD

The present invention is related to spin device for detecting magnetic field changes, more particularly to a spin device that forms an asymmetric structure at an interface between a magnetic seed layer and a magnetic free layer, and that has a high sensitivity and robustness to noise.

### BACKGROUND ART

A spin device uses the magnetization of ferromagnetic layers to detect a change in resistance or perform an operation that detects a change in magnetic field. For example, when spin transfer torque is used, the resistance of the spin device is determined by the magnetization direction of the free layer and the pinned layer. The resistance state of the spin device expresses the state of the data in the spin memory. In addition, the spin device can be used as a magnetic sensor when the Hall voltage due to the movement of the magnetic domain in a ferromagnetic material is detected.

A representative device for magnetic sensors is the Hall sensor. Hall sensors are devices that have a cross-bar shape and convert changes in the magnetic field passing through a semiconductor layer into a voltage difference. In addition to Hall sensors, magneto-resistive sensors, which utilize magnetoresistance, take advantage of the phenomenon that the electrical resistance of a material changes in response to the presence of a magnetic field. Magneto-resistive sensors utilize anisotropic magneto-resistance (AMR), giant magneto-resistance (GMR), or tunneling magneto-resistance (TMR).

In particular, anisotropic magneto-resistance is an effect exhibited by ferromagnetic metals and their alloys, and is additional effect to the normal magneto-resistance effect. It refers to the phenomenon that when the direction of current and magnetization through a ferromagnetic material is parallel to each other, the resistance is maximum, and when the direction of current and magnetization is perpendicular to each other, the resistance is minimum. This is due to the spin-orbit interaction, which depends on the magnetic easy-axis of the ferromagnet and the angle between the external magnetic field and the current, and is known to have relatively low sensitivity.

Giant magneto-resistance is a phenomenon in which two magnetic layers with parallel and antiparallel magnetization directions have significantly resistance difference. It is realized through a multilayer structure, where a conductive layer is formed between two magnetic layers.

The tunnel magneto-resistance uses a spin tunnel phenomenon and has the advantage of high regeneration sensitivity. The non-magnetic layer placed between the two magnetic layers is formed as an insulator, which utilizes the phenomenon that the tunneling effect of the insulator changes with the magnetic directions of the pinned layer and free layer.

The magnetic sensor described above is being considered for various applications. In particular, a number of sensors that measure the magnetic field applied in the three axial directions are used in automobile parts for rotation and positioning of objects. In general, in order to detect changes in the magnetic field applied in the three axial directions, it is not possible to use a single magnetic sensor alone, and it is necessary to combine two separately magnetic sensors through a packaging process. For example, a conventional linear Hall sensor may be arranged to detect magnetic field changes perpendicular to the surface of the chip, and a GMR sensor may be used to detect magnetic field changes in the in-plane direction. As described above, the integration of multiple magnetic sensors into a single package requires complex structures for wire bonding or connection to external wiring.

In addition, AMR sensors utilize the spin orbit torque, but require relatively large currents to switch the magnetization. In addition, impurities in the ferromagnetic material increase the driving power. This is explained in detail as follows

When the magnetization direction of the spins is controlled using the spin orbit torque (SOT), it has the advantage of causing a switching operation with a smaller amount of current compared to the spin transfer torque (STT) used in conventional spin memories. However, the spin device using SOT has a multilayer structure, and the magnetic seed layer and the magnetic free layer in the multilayer structure have a symmetrical structure. The symmetrical structure means that the profile of the magnetic seed layer and the magnetic free layer have the same profile, i.e., due to their mutual identical shape, the edge of the interface between the magnetic seed layer and the magnetic free layer shows relatively large defects. The edge defect requires a lot of power to move the magnetic domain wall, and when the spin device is operated as a magnetic sensor, the magnetization direction changes suddenly jumping), hence it difficult to measure the magnetic field.

Therefore, a new spin device structure in which the movement of the magnetic domain wall does not occur at the edge of the magnetic free layer or the movement occurs through the center of the magnetic free layer is still required.

### DETAILED DESCRIPTION OF INVENTION

### Technical Problem

The present invention is directed to providing a spin device in which a magnetic domain wall moves stably and a jumping phenomenon of the magnetic domain wall is prevented.

### Technical Solution

One aspect of the present invention provides a spin device. The spin device comprises a magnetic seed layer formed on a substrate and having a non-magnetic heavy metal, a magnetic free layer formed on the magnetic seed layer and having a ferromagnetic material having a vertical magnetic anisotropy, and an oxide layer formed on the magnetic free layer for imparting the vertical magnetic anisotropy to the magnetic free layer. A width of the magnetic seed layer is smaller than a width of the magnetic free layer, and a magnetic domain wall of the magnetic free layer moves at a region abutting the magnetic seed layer.

Another aspect of the present invention provides a spin device. The spin device comprises an oxide layer formed on a substrate, a magnetic free layer formed on the oxide layer and made of a ferromagnetic material having perpendicular magnetic anisotropy, and a magnetic seed layer formed on the magnetic free layer and having a non-magnetic heavy metal. A width of the magnetic seed layer is smaller than that of the magnetic free layer, and a magnetic domain wall in the magnetic free layer moves in a region other than an edge region of the magnetic free layer, and the magnetic seed layer is characterized in that it has a width of 36.4% to 80% of the width of the magnetic free layer.

### Advantageous Effects

According to the present invention, the width of the magnetic seed layer is intentionally set to be smaller than that of the magnetic free layer. The magnetic free layer, being ferromagnetic, contains the highest density of crystal defects at its edges. When magnetic domain wall movement is induced by spin orbit torque, these defects can unpredictably trigger jumping phenomena. Hence, present invention enables the magnetic domain wall to avoid the edges of the magnetic free layer during movement. This design ensures stable magnetic domain wall movement and secures operational linearity. Furthermore, it facilitates reversible domain wall movement. These characteristics are applicable to spin-based memory devices, Hall sensors, and neural network devices. In particular, noise caused by the jumping phenomenon can be effectively suppressed, and operational linearity is ensured, allowing the fabrication of reliable spin devices.

### DESCRIPTION OF DRAWINGS

FIG. 1 is a cross-sectional view of a spin device according to a preferred embodiment of the present invention.

FIG. 2 is another cross-sectional view of the spin device according to a preferred embodiment of the present invention.

FIG. 3 is a top planar view of the spin device shown in FIG. 1, according to a preferred embodiment of the present invention.

FIG. 4 is the top image of the spin device fabricated according to the manufacturing example of the present invention.

FIG. 5 is an image of magnetic domain wall movement in the spin device of

FIG. 6 is a graph measuring the Hall resistance corresponding to the magnetic domain wall movement in the spin device of FIG. 4 according to the manufacturing example.

FIG. 7 is an image of magnetic domain wall movement in a spin device according to the comparative manufacturing example.

FIG. 8 is image showing the magnetic domain wall jumping phenomenon observed in the spin device according to the comparative example of the present invention.

### MODES OF THE INVENTION

The invention is subject to various modifications and can take many forms, certain embodiments of which are illustrated in the drawings and described in detail herein. However, this is not intended to limit the invention to any particular disclosed form, and is to be understood to include all modifications, equivalents, or substitutions that fall within the scope of the thought and skill of the present invention. In the description of each drawing, like reference numerals are used for like components.

Unless otherwise defined, all terms used herein, including technical or scientific terms, have the same meaning as commonly understood by one of ordinary skill in the art to which this invention belongs. Such terms, as defined in commonly used dictionaries, shall be construed to have a meaning consistent with the meaning they have in the context of the relevant art and shall not be construed to have an idealized or unduly formal meaning unless expressly defined in this application.

Hereinafter, embodiments of the present invention will be described in detail with reference to the accompanying drawings.

### Embodiment

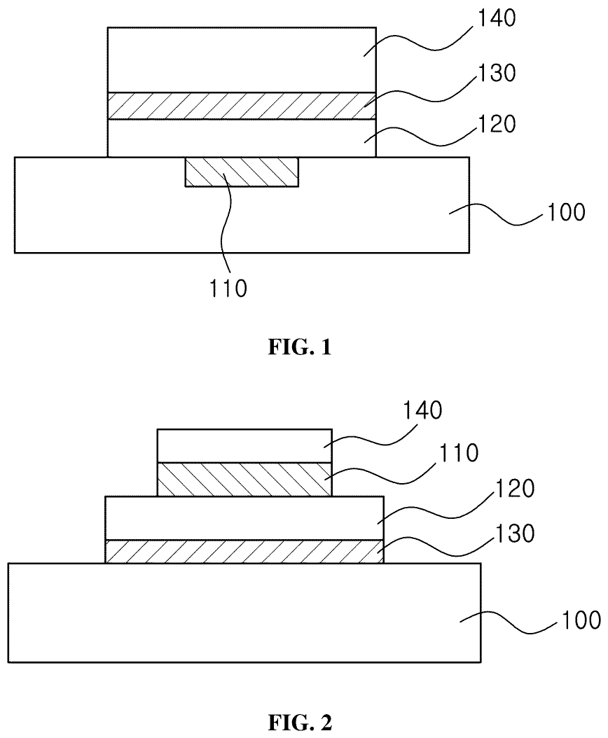

FIG. 1 is a cross-sectional view of a spin device according to a preferred embodiment of the present invention.

Referring to FIG. 1, spin device has a substrate 100, a magnetic seed layer 110, a magnetic free layer 120, an oxide layer 130, and an upper electrode 140.

The substrate 100 functions as a support for the formation of the upper layers, and is selected as a material that does not affect the properties of the upper layers. To this end, the substrate 100 is preferably an insulating material. For example, the substrate 100 may have a SiO2 material.

A magnetic seed layer 110 is formed on the substrate 100. The magnetic seed layer 110 is a non-magnetic heavy metal, and includes Ta, W, Hf, Mo, Nb, Ti, Pt, or Pd. The magnetic seed layer 110 may be provided in a depressed shape in the substrate 100. Thus, the upper plane of the magnetic seed layer 110 is preferably co-planar with the upper plane of the substrate 100. To this end, the magnetic seed layer 110 can be formed by etching a portion of the substrate 100 to form a trench, and embedding the trench with a non-magnetic heavy metal to form the magnetic seed layer 110.

A magnetic free layer 120 is formed on the magnetic seed layer 110. The magnetic free layer 120 is ferromagnetic and comprises Co, Fe, Ni, Mn, or an alloy thereof, and preferably has CoFeB, NiFe, CoPd, CoPt, FePt, or FePd. Furthermore, the magnetic free layer 120 is formed according to the crystal structure of the magnetic seed layer 110, and magnetic domain wall of the magnetic free layer 120 is moved by the current and external magnetic field applied horizontally about the surface of the magnetic free layer 120.

The magnetic free layer 120 completely covers the surface of the magnetic seed layer 110 and has a wider width than the magnetic seed layer 110. Therefore, the change of the magnetic moment due to the current flowing through the magnetic seed layer 110 and the external magnetic field applied in a direction parallel to the current occurs in the central region of the magnetic free layer 120, and the movement of the magnetic domain wall also occurs mainly in the central region of the magnetic free layer 120.

An oxide layer 130 is formed on the magnetic free layer 120. A representative material that can be used as the oxide layer 130 is MgO. The oxide layer 130 may have thickness of several nm, and vertical magnetic anisotropy in the magnetic free layer 120 can be secured due to thin thickness.

Furthermore, an upper electrode 140 is formed on the oxide layer 130. The upper electrode 140 may be any metal having a conductive material.

In FIG. 1, the magnetic free layer 120 and the oxide layer 130 have the same profile and thus have the same width with respect to each other. However, the magnetic seed layer 110 has a smaller width than the magnetic free layer 120 and the oxide layer 130. Furthermore, the magnetic free layer 120 and the oxide layer 130 have a roughly cross-shaped structure, and the magnetic seed layer 110 also has also cross-shaped structure. However, the cross-shaped structure of the magnetic seed layer 110 is smaller than that of the magnetic free layer 120, and the cross-shaped structure of the magnetic seed layer 110 is preferably completely contained within the cross-shaped structure of the magnetic free layer 120.

Furthermore, the magnetic seed layer 110 may be provided in a recessed form on the substrate 100, or may be provided in a protruding form on the substrate 100. When the magnetic seed layer 110 is provided in a protruding form on the substrate 100, it is preferable that a non-magnetic insulator is disposed on the side of the magnetic seed layer 110. So, the surface area of the magnetic free layer 120 in contact with the magnetic seed layer 110 is small than the surface area of the magnetic free layer 120, and any configuration is possible as long as the magnetic free layer 120 includes the shape of the magnetic seed layer 110 when viewed in the top view in FIG. 1.

In particular, when the magnetic domain wall of the magnetic free layer 120 moves in response to the application of a current or voltage, it is preferred that the width of the moving magnetic domain wall is smaller than the width of the magnetic free layer 120. For example, in FIG. 1, when the magnetic domain wall of the magnetic free layer 120 moves in the direction of entering the paper surface, the width of the magnetic domain wall is preferably smaller than the width of the magnetic free layer 120.

FIG. 2 is another cross-sectional view of the spin device according to a preferred embodiment of the present invention.

Referring to FIG. 2, the spin device includes a substrate 100, an oxide layer 130, a magnetic free layer 120, a magnetic seed layer 110, and an upper electrode 140.

The oxide layer 130 is formed on the substrate 100, and the magnetic free layer 120 and the magnetic seed layer 110 are sequentially formed on the oxide layer 130.

The material of each component disclosed in FIG. 2 is the same as described in FIG. 1. However, FIG. 2 has a reverse structure compared to that of FIG. 1. In addition, the width of the magnetic seed layer 110 is smaller than that of the magnetic free layer 120, and the magnetic domain wall of the magnetic free layer 120 moves due to the spin orbit torque generated by the pulse current and horizontal magnetic field applied to the magnetic seed layer 110. The movement of the magnetic domain wall in the magnetic free layer 120 is the same as described in FIG. 1. Additionally, when viewed from the top of FIG. 2, it is preferable that the magnetic seed layer 110 is included within the shape of the magnetic free layer 120.

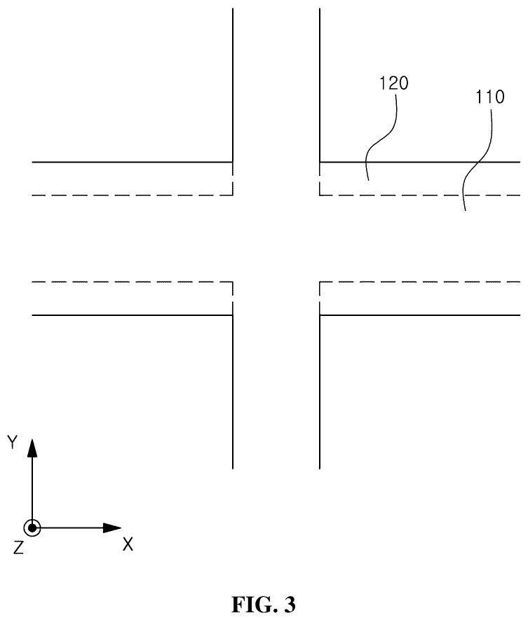

FIG. 3 is a top planar view of the spin device shown in FIG. 1, according to a preferred embodiment of the present invention.

Referring to FIG. 3, the area represented by the dotted lines indicates the outline of the magnetic seed layer 110, and the area represented by the solid lines indicates the outline of the magnetic free layer 120. The magnetic seed layer 110 is made of a non-magnetic heavy metal, while the magnetic free layer 120 is made of a ferromagnetic metal material. Therefore, electrically, the magnetic seed layer 110 and the magnetic free layer 120 can be considered to be short-circuited. Furthermore, the top planar view of FIG. 2 has the same shape as FIG. 3 except that the positions of the magnetic seed layer 110 and the magnetic free layer 120 are switched. Therefore, the movement of the magnetic domain wall in the magnetic free layer 120 due to the pulse current and external magnetic field supplied to the magnetization magnetic seed layer 110 follows the mechanism described below.

As shown in the top planar view, the magnetic seed layer 110 and the magnetic free layer 120 have a cross-shaped structure, with the magnetic free layer 120 having a wider width compared to the magnetization magnetic seed layer 110. However, it is preferable that the center line of the magnetic seed layer 110 coincides with the center line of the magnetization magnetic free layer 120.

Since the width of the region extended along the x-axis and the width of the region extended along the y-axis may differ, the width ratio of the magnetic seed layer 110 to the magnetic free layer 120 is preferably set between 36.4% and 80%. This means that, within the cross-shaped structure, the width of the magnetic seed layer along the current direction parallel direction) is preferably 36.4% to 80% of the width of the magnetic free layer.

When a current and an external magnetic field are applied along the x-direction to the magnetic seed layer 110, the spin orbit torque causes the magnetic domain wall in the magnetic free layer 120 to move. For example, it is assumed that, before the application of the current and the external magnetic field, the magnetic free layer 120 has perpendicular magnetic anisotropy oriented into the paper surface. When the current and external magnetic field are applied along the x-direction to the magnetic seed layer 110 as mentioned, a force for magnetization switching is generated in the magnetic free layer 120 by the spin orbit torque, resulting in the movement of the magnetic domain wall. If the current applied in the x-direction takes the form of a pulse train, the magnetic domain wall moves stepwise along the x-direction.

However, since the magnetic seed layer 110 is made of a non-magnetic heavy metal, defects may exist within the crystal, and scattering of free electrons may occur, but there is no phenomenon where the supplied current becomes concentrated in a specific region. On the other hand, in the magnetic free layer 120, which is the region where the spin orbit torque is generated, the presence of defects significantly affects the movement of the magnetic domain wall. As shown in FIG. 3, the edge region of the magnetic free layer 120 has more defects compared to the central region. Defects may take various forms, such as reduced crystallinity or the occurrence of vacancies. Due to these defects, irregularities in the magnetic domain wall movement tend to increase in the edge region, which may speed up or slow down the movement of the magnetic domain walls. In other words, the irregular structure in the edge region can lead to irregular magnetic domain wall movement, and the magnetic domain wall may progress only through the edge region, causing a jumping phenomenon where the magnetic domain wall forms largely in specific regions.

The jumping phenomenon of magnetic domain wall can result in malfunctioning of the spin device and reduce reliability in repeated magnetic field sensing operations.

However, in FIG. 3, the region of the magnetic free layer 120 in contact with the magnetic seed layer 110 corresponds to a central partial region rather than the entire magnetic free layer. Therefore, the region of the magnetic free layer 120 that contacts the magnetic seed layer 110 avoids the edge region, so that irregular movement of magnetic domain wall due to defects don't occur. As a result, under the condition where pulse currents are applied stepwise, the magnetic domain wall can move stably.

### Manufacturing Example

A spin device is fabricated. SiO2 is used as the substrate, and tungsten W) is used as the magnetic seed layer. The thickness of the magnetic seed layer is 1.2 nm. Furthermore, the magnetic free layer, which fully covers the magnetic seed layer, is made of CoFeB and has a thickness of 1.2 nm. On the magnetic free layer, an oxide layer of MgO with a thickness of 1 nm is formed. An upper electrode of Ta is then formed on the oxide layer with a thickness of 3 nm.

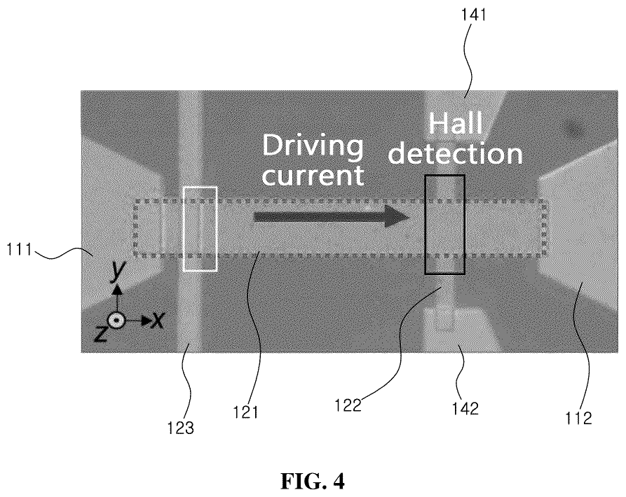

FIG. 4 is the top image of the spin device fabricated according to the manufacturing example of the present invention.

The spin device has a cross-shaped structure. A first region 121 extending in the x-axis direction intersects with a second region 122 extending in the y-axis direction, and an additional region 123 extending in the y-axis direction is formed separately from the second region 122. The additional region 123 does not substantially affect the operation of the spin device but is used during the initial movement operation of magnetic domain wall by applying an additional bias or pulse to initiate the magnetic domain wall movement. Therefore, the additional region can be omitted when designing the spin device. If the additional region is omitted, the magnetic domain wall movement can be initiated by adjusting the magnitude or duty cycle of the pulse current applied to the first region 121.

The width of the first region 121 is 4 μm, and the width of the second region 122 is 2 μm. Additionally, the first region 121 consists of a stacked structure of the magnetic seed layer, magnetic free layer, oxide layer and upper electrode, and the second region 122 has the same structure. However, the first electrode 111 and second electrode 112 in the first region 121 are electrically connected to the magnetic seed layer, and a magnetic field and pulse current are applied from the first electrode 111 toward the second electrode 112.

The width of the magnetic seed layer in the first region 121 is 2 μm, while the widths of the magnetic free layer and the oxide layer are 4 μm. Thus, in the first region 121, the magnetic free layer completely covers the magnetic seed layer. The upper electrode formed on the uppermost layer of the first region 121 and the second region 122 is electrically connected to the third electrode 141 and the fourth electrode 142 in the second region 122.

A pulse current and external magnetic field are applied parallel to the direction in which the first region 121 extends. At the interface between the magnetic seed layer and the magnetic free layer, spin orbit torque is generated due to the pulse current and external magnetic field, causing the perpendicular magnetic anisotropy of the magnetic free layer to switch. For example, the magnetic moment initially oriented into the paper surface transitions to a magnetic moment oriented outward from the paper surface as the pulse current is applied. As the pulse current accumulates, the region with switched magnetization expands from the vicinity of the first electrode in the first region 121 toward the vicinity of the second electrode.

When the region with switched magnetization reaches the intersection of the first region 121 and the second region 122, a change in the Hall voltage occurs between the third electrode 141 and the fourth electrode 142. This allows for the detection of the accumulated pulses.

### Comparative Manufacturing Example

To compare the performance of the spin device fabricated in the manufacturing example, a comparative spin device is produced.

The thickness and material of the layers forming the spin device are identical to those in the manufacturing example. Additionally, the spin devices share the same cross-shaped structure. However, the width of the magnetic seed layer is the same as that of the magnetic free layer. Consequently, both the magnetic seed layer and the magnetic free layer have a width of 4 μm.

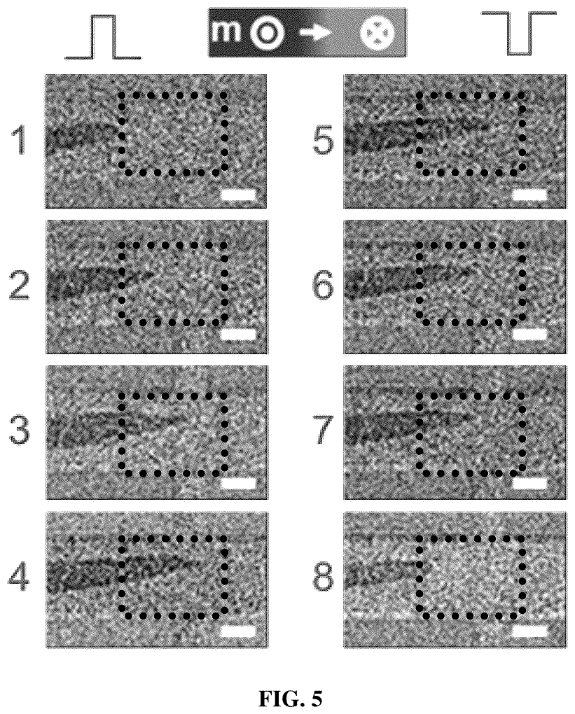

FIG. 5 is an image of magnetic domain wall movement in the spin device of FIG. 2 according to the manufacturing example of the present invention.

Referring to FIG. 5, the movement of the magnetic domain wall cannot be observed using a conventional optical microscope. However, when a MOKE (magneto-optical Kerr effect) microscope is used, shading varies according to the magnetization state of the magnetic domain wall.

The applied pulse current has a level of (+)12 V and is applied during 1 msec. As the number of applications increases, the magnetic domain wall, which has a magnetic moment emitted outward the paper surface, moves to the right. However, the change in the magnetic domain wall does not occur across the entire magnetic free layer but follows the profile of the underlying magnetic seed layer. Therefore, magnetic domain wall movement is detected only in the central region of the magnetic free layer. In FIG. 5, the dotted region corresponds to the area where Hall voltage is detected, which is located at the intersection of the first and second regions in the cross-shaped structure of FIG. 4. After four applications of a (+) pulse current, four applications of (−) pulse current having the 12 V magnitude are applied. Upon applying the (−) pulse current, the magnetic domain wall moves back to the left, returning to its original state.

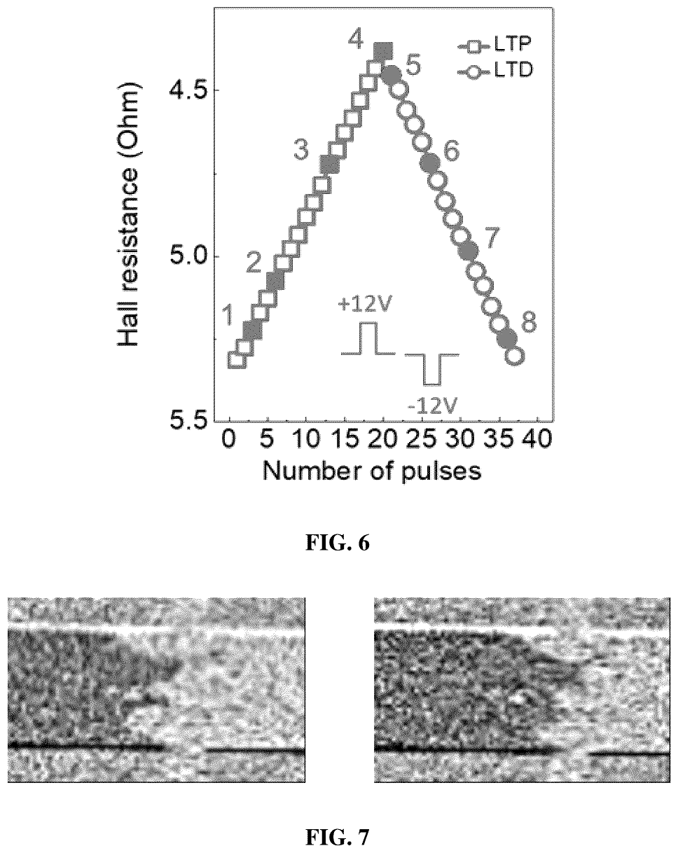

FIG. 6 is a graph measuring the Hall resistance corresponding to the magnetic domain wall movement in the spin device of FIG. 4 according to the manufacturing example.

Referring to FIGS. 5 and 6, the Hall resistance decreases linearly with the application of the positive pulse current. The numbers 1 through 8 in the graph of FIG. 6 correspond to the numbers assigned to the respective images in FIG. 5. Furthermore, symbol “□”, indicates that cumulative positive pulses strengthen the magnetic domain wall movement, and is labeled as “LTP”. Symbol “o” represents regression of the enhanced magnetic domain wall movement with cumulative negative pulses, is labeled as “LTD”.

At number 4, the Hall resistance reaches its minimum value due to the cumulative application of the pulse current. Subsequently, when a negative pulse is applied, the magnetic domain wall retreats to the left, and the Hall resistance increases linearly. At number 8, when the pulse current is applied again, the Hall resistance returns to its initial state corresponding to the first pulse application.

In FIG. 6, it is observed that the Hall resistance changes linearly with the application of pulse currents, and FIG. 4 confirms that magnetic domain wall movement occurs reversibly.

FIG. 7 is an image of magnetic domain wall movement in a spin device according to the comparative manufacturing example.

Referring to FIG. 7, the magnetic seed layer and magnetic free layer have the same width. The phenomenon of magnetic domain wall movement caused by the pulse current supplied through the magnetic seed layer and the externally magnetic field in the same direction with the pulse current is identical to that described in FIG. 3.

Additionally, the applied pulse current has a level of (+)12 V and is applied during 1 msec. When observing the shape of the magnetic domain wall at arbitrary points during cumulative pulse current application, the magnetic domain wall exhibits highly irregular movement. The movement pattern at the ends of the magnetic domain wall is also highly irregular at any given moment of pulse application. This is due to structural defects in the crystalline structure of the magnetic free layer.

The sides of the magnetic free layer contain more defects compared to the central region. Due to these defects, the SOT (spin orbit torque) phenomenon occurs irregularly, and the magnetic domain wall movement also occurs irregularly. Therefore, even when identical pulse currents are applied, the behavior of the magnetic domain wall is irregular, and the generation of Hall voltage or Hall resistance occurs nonlinearly.

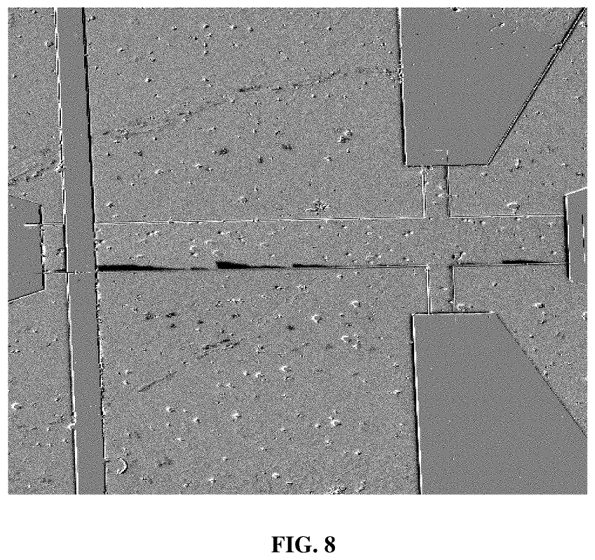

FIG. 8 is image showing the magnetic domain wall jumping phenomenon observed in the spin device according to the comparative example of the present invention.

Referring to FIG. 8, irregular magnetic domain wall movement is observed when a pulse current is applied to the spin device shown in FIG. 7. When alternating pulses with positive and negative levels are repeatedly applied, the magnetic domain wall advances and retreats. At certain arbitrary points during the repeated application of pulse currents, the spin device of FIG. 7 exhibits the jumping phenomenon. Specifically, the magnetic domain wall does not move linearly, and regions of switched magnetization appear at unspecified points along the edges of the magnetic free layer. These regions of switched magnetization are visible as darker shading compared to other areas. This magnetic domain wall jumping phenomenon is identified as noise in devices such as Hall sensors and causes malfunction of the spin device.

As described above, when the magnetic seed layer and the magnetic free layer have the same width, the magnetic domain wall jumping phenomenon occurs due to the numerous defects distributed along the edges of the magnetic free layer.

Table 1 investigates the range of widths of the magnetic seed layer relative to the width of the magnetic free layer. The width of the magnetic seed layer remains fixed, while the width of the magnetic free layer is varied to determine whether the jumping phenomenon occurs. Additionally, as shown in FIG. 4, the anomalous Hall effect is measured at the third and fourth electrodes, and the change of Hall resistance is recorded after applying four pulses of current. In the present invention, the width of the magnetic seed layer is fixed and the width of the magnetic free layer is changed, but the width of the magnetic free layer can be fixed and the width of the magnetic seed layer can be changed according to the performance of the process equipment possessed by those skilled in the art. Furthermore, the significant parameter in the table 1 is the ratio of the width of the magnetic seed layer to the width of the magnetic free layer. In this embodiment, the width ratio is varied from 33.3% to 100%, and observations are made accordingly. The change of Hall resistance is defined as the difference in Hall resistance measured after applying four pulse currents compared to that measured after applying a single pulse current, as described in FIG. 5. Accordingly, the Hall resistance measurements for each sample follow the procedure illustrated in FIG. 4.

TABLE 1

| | width of | width of | | presence of | |
|---|---|---|---|---|---|
| sample | magnetic seed | magnetic free | | jumping | change of Hall |
| number | layer | layer | | phenomenon | resistance |
| 1 | 2 um | 2 | um | yes | 83% |
| 2 | 2 um | 2.5 | um | no | 93% |
| 3 | 2 um | 3 | um | no | 95% |
| 4 | 2 um | 3.5 | um | no | 98% |
| 5 | 2 um | 4 | um | no | 100% |
| 6 | 2 um | 4.5 | um | no | 103% |
| 7 | 2 um | 5 | um | no | 101% |
| 8 | 2 um | 5.5 | um | no | 97% |
| 9 | 2 um | 6 | um | no | 87% |

Referring to Table 1, it can be observed that in Sample 1, where the width of the magnetic seed layer and the magnetic free layer are identical, a jumping phenomenon occurs. Consequently, when a pulse current is applied to this sample, the irregular movement of the magnetic domain wall generates significant noise in the Hall voltage, leading to malfunction of the spin device.

In Samples 2 through 6, as the ratio of the width of the magnetic seed layer to the magnetic free layer decreases, the variation in Hall resistance shows a tendency to increase. This is attributed to the increase in the width of the magnetic free layer formed on magnetic seed layer having the fixed width. Specifically, since the pulse current supplied through the magnetic seed layer remains constant, an increase in the width of the magnetic free layer in contact with the seed layer enhances the crystallinity at the junction interface. Consequently, the magnetic domain wall movement becomes smoother and more reversible, resulting in a tendency for the Hall resistance variation to increase.

In Samples 8 and 9, the jumping phenomenon is not observed, but the variation in Hall resistance tends to decrease compared to Sample 7. This is due to the excessively wide width of the magnetic free layer relative to the magnetic seed layer. The magnetic domain wall movement and magnetization switching induced by spin orbit torque (SOT) should occur primarily in the region of the magnetic free layer directly in contact with the magnetic seed layer. However, when the magnetic free layer is excessively wide, the pulse current excessively diffuses within it, weakening the strength of the spin orbit torque and preventing strong domain wall formation. As a result, the variation in Hall resistance shows a slight decreasing trend.

From a practical perspective, if the Hall resistance variation falls below 90%, it is considered equivalent to a decline in sensing sensitivity, significantly reducing the usability of the device as a sensing device. Thus, spin devices should be fabricated within the range of Samples 2 through 8. Specifically, it is preferable for the magnetic seed layer to have a width of 36.4% to 80% relative to the width of the magnetic free layer.

In the present invention, the width of the magnetic seed layer is intentionally set to be smaller than that of the magnetic free layer. The magnetic free layer, being ferromagnetic, contains the highest density of crystal defects at its edges. When magnetic domain wall movement is induced by spin orbit torque, these defects can unpredictably trigger jumping phenomena. Hence, present invention enables the magnetic domain wall to avoid the edges of the magnetic free layer during movement. This design ensures stable magnetic domain wall movement and secures operational linearity. Furthermore, it facilitates reversible domain wall movement. These characteristics are applicable to spin-based memory devices, Hall sensors, and neural network devices. In particular, noise caused by the jumping phenomenon can be effectively suppressed, and operational linearity is ensured, allowing the fabrication of reliable spin devices.

1. A spin device comprising:
a magnetic seed layer formed on a substrate and having a non-magnetic heavy metal;
a magnetic free layer formed on the magnetic seed layer and having a ferromagnetic material having a vertical magnetic anisotropy; and
an oxide layer formed on the magnetic free layer for imparting the vertical magnetic anisotropy to the magnetic free layer,
wherein a width of the magnetic seed layer is smaller than a width of the magnetic free layer, and a magnetic domain wall of the magnetic free layer moves at a region abutting the magnetic seed layer.

2. The spin device of claim 1, wherein the magnetic seed layer has recessed shape on the substrate, and forms a co-plane with the substrate.

3. The spin device of claim 1, wherein the width of the magnetic seed layer is 36.4% to 80% of the width of the magnetic free layer.

4. The spin device of claim 3, wherein the magnetic domain wall of the magnetic free layer moves in a region other than an edge region of the magnetic free layer.

5. The spin device of claim 1, wherein the magnetic free layer completely covers the magnetic seed layer.

6. The spin device of claim 1, wherein the magnetic seed layer, the magnetic free layer and the oxide layer have a cross-shaped structure, and the cross-shaped structure of the magnetic seed layer is covered in the cross-shaped structure of the magnetic free layer.

7. The spin device of claim 6, wherein the cross-shaped structure comprises,
a first region formed between a first electrode and a second electrode, in which the magnetic domain wall moves; and
a second region formed between a third electrode and a fourth electrode, and intersecting the first region, for detecting movement of the magnetic domain wall in the region intersecting the first region.

8. The spin device of claim 7, wherein the width of the magnetic seed layer within the first region is smaller than the width of the magnetic free layer.

9. The spin device of claim 7, wherein a region where the first region and the second region intersect has a linear change of resistance when a pulse current is applied between the first electrode and the second electrode.

10. The spin device of claim 9, when the pulse current is applied in a positive direction while accumulating between the first electrode and the second electrode, the resistance between the third electrode and the fourth electrode linearly decreases, and when the pulse current is applied in a negative direction while accumulating, the resistance between the third electrode and the fourth electrode linearly increases.

11. A spin device comprising:
an oxide layer formed on a substrate;
a magnetic free layer formed on the oxide layer and made of a ferromagnetic material having perpendicular magnetic anisotropy; and
a magnetic seed layer formed on the magnetic free layer and having a non-magnetic heavy metal,
wherein a width of the magnetic seed layer is smaller than that of the magnetic free layer, and a magnetic domain wall in the magnetic free layer moves in a region other than an edge region of the magnetic free layer,
and the magnetic seed layer is characterized in that it has a width of 36.4% to 80% of the width of the magnetic free layer.
